(19) United States
(12) Patent Application Publication
(10) Pub. No.: US 2026/0231433 A1
(43) Pub. Date: Aug. 6, 2026

(54) MAGNETORESISTIVE EFFECT ELEMENT AND MAGNETIC MEMORY DEVICE

(71) Applicant: The University of Tokyo, Tokyo (JP)

(72) Inventors: Satoru Nakatsuji, Tokyo (JP); Tomoya Higo, Tokyo (JP)

(73) Assignee: The University of Tokyo, Tokyo (JP)

(21) Appl. No.: 19/147,037

(22) PCT Filed: Jan. 15, 2024
(86) PCT No.: PCT/JP2024/000871

§ 371 Date: Oct. 28, 2025

Related U.S. Application Data
(60) Provisional application No. 63/479,747, filed on Jan. 13, 2023.

(51) Int. Cl. H10B 61/00; G11C 11/16; H10N 50/10

(52) U.S. Cl. CPC H10B 61/20; G11C 11/161; H10N 50/10

(57) ABSTRACT

A magnetoresistance element includes: a free layer made of an antiferromagnet; a non-magnetic layer stacked on the free layer; a pinned layer stacked on the non-magnetic layer and made of an antiferromagnet; and a pinning layer stacked on the pinned layer and made of a magnetic material that is magnetically harder than the pinned layer.

### TECHNICAL FIELD

The present invention relates to a magnetoresistance element and a magnetic memory device.

### BACKGROUND ART

Antiferromagnets have faster spin dynamics than ferromagnets and have therefore attracted attention as materials for high-speed magnetic memory elements. For example, Patent Literature 1 discloses a magnetic memory element including an antiferromagnetic layer whose magnetic order (magnetization) is reversible. The antiferromagnetic layer can function as a free layer of a magnetoresistance element such as a magnetic tunnel junction (MTJ).

### CITATION LIST

### Patent Literature

Patent Literature 1: WO2022/220251

### SUMMARY OF INVENTION

### Technical Problem

In recent years, the miniaturization of magnetic memory elements has been increasingly required for their application in various magnetic devices, such as magnetic random access memories (MRAMs), spin memristors, and switching elements. However, as these elements become smaller, thermal fluctuations of spin have become a growing concern. Therefore, the magnetoresistance elements are required to establish a hard magnetic order in a pinned layer which serves as a reference layer.

An object of the present invention is to provide a magnetoresistance element and a magnetic memory device capable of establishing a pinned layer having a hard magnetic order with respect to a free layer made of an antiferromagnet.

### Solution to Problem

A magnetoresistance element according to a first aspect of the invention includes: a free layer made of an antiferromagnet; a non-magnetic layer stacked on the free layer; a pinned layer stacked on the non-magnetic layer and made of an antiferromagnet; and a pinning layer stacked on the pinned layer and made of a magnetic material that is magnetically harder than the pinned layer.

A magnetic memory device according to a second aspect of the invention includes: a free layer made of an antiferromagnet; a non-magnetic layer stacked on the free layer; a pinned layer stacked on the non-magnetic layer and made of an antiferromagnet; a pinning layer stacked on the pinned layer and made of a magnetic material that is magnetically harder than the pinned layer; and a spin Hall layer that is in contact with the free layer and configured to exhibit a spin Hall effect when an electric current flows through the spin Hall layer parallel to an interface with the free layer.

A magnetic memory device according to a third aspect of the invention includes: a free layer made of an antiferromagnet; a non-magnetic layer stacked on the free layer; a pinned layer stacked on the non-magnetic layer and made of an antiferromagnet; a pinning layer on the pinned layer and made of a magnetic material that is magnetically harder than the pinned layer; and a pair of electrode terminals configured to introduce an electric current into the free layer in an out-of-plane direction.

A magnetoresistance element according to a fourth aspect of the invention includes: a pinned layer made of an antiferromagnet; and a pinning layer that is magnetically harder than the pinned layer.

A magnetoresistance element according to a fifth aspect of the invention includes: a free layer made of an antiferromagnet; a non-magnetic layer stacked on the free layer; a pinned layer stacked on the non-magnetic layer and made of a ferromagnet; and a pinning layer stacked on the pinned layer and made of a magnetic material that is magnetically harder than the ferromagnet of the pinned layer.

In a method of controlling a magnetic memory device according to a sixth aspect of the invention, the magnetic memory device includes: a free layer made of an antiferromagnet; a non-magnetic layer stacked on the free layer; a pinned layer stacked on the non-magnetic layer and made of an antiferromagnet; and a pinning layer stacked on the pinned layer and made of a magnetic material that is magnetically harder than the pinned layer. The method includes: manipulating a magnetic order in the free layer due to spin torque.

In a method of controlling a magnetic memory device according to a seventh aspect of the invention, the magnetic memory device includes: a free layer made of an antiferromagnet; a non-magnetic layer stacked on the free layer; a pinned layer stacked on the non-magnetic layer and made of an antiferromagnet; a pinning layer stacked on the pinned layer and made of a magnetic material that is magnetically harder than the pinned layer; and a spin Hall layer that is in contact with the free layer and configured to exhibit a spin Hall effect when an electric current flows through the spin Hall layer parallel to an interface with the free layer. The method includes: reversing a magnetic order in the free layer due to spin-orbit torque induced by the spin Hall effect.

In a method of controlling a magnetic memory device according to a eighth aspect of the invention, the magnetic memory device includes: a free layer made of an antiferromagnet; a non-magnetic layer stacked on the free layer; a pinned layer stacked on the non-magnetic layer and made of an antiferromagnet; and a pinning layer stacked on the pinned layer and made of a magnetic material that is magnetically harder than the pinned layer. The method includes: causing a write current to flow through the free layer in an out-of-plane direction, thereby reversing a magnetic order in the free layer due to spin-transfer torque.

### Advantageous Effects of Invention

As described above, according to the disclosed aspects, by providing the pinning layer that fixes the magnetic order of the pinned layer, it is possible to establish the pinned layer having a hard magnetic order with respect to the free layer made of an antiferromagnet whose magnetic order is reversible.

### BRIEF DESCRIPTION OF DRAWINGS

FIG. 1 is a schematic diagram illustrating a structure of a magnetoresistance element according to one embodiment.

FIG. 2 is a schematic diagram illustrating a structure of a magnetoresistance element according to a modification.

FIG. 3A is a schematic diagram illustrating a structure of a magnetoresistance element according to another modification.

FIG. 3B is a schematic diagram illustrating a structure of a magnetoresistance element according to yet another modification.

FIG. 4 illustrates an X-ray diffraction pattern obtained from a coupling film including Mn₃Sn and NiMn layers.

FIG. 5 illustrates an X-ray diffraction pattern obtained from a multilayer film including permalloy and NiMn layers.

FIG. 6 is a graph illustrating magnetic field dependence of Hall resistivity of the coupling film including the Mn₃Sn and NiMn layers.

FIG. 7 is a graph illustrating the magnetic field dependence of Hall resistivity of the coupling film including the Mn₃Sn and NiMn layers.

FIG. 8 is graph illustrating the magnetic field dependence of Hall resistivity of the coupling film including the Mn₃Sn and NiMn layers.

FIG. 9 is a graph illustrating magnetic field dependence of magnetization of the multilayer film including the permalloy layer and the NiMn layer.

FIG. 10 illustrates an X-ray diffraction pattern obtained from a coupling film including Mn₃Sn and MnN layers.

FIG. 11 is a graph illustrating magnetic field dependence of Hall resistivity of the coupling film including the Mn₃Sn and MnN layers.

FIG. 12 is a graph illustrating a relation between a thickness of a spacer layer and a bias magnetic field in the coupling film including the Mn₃Sn and NiMn layers.

FIG. 13 is a schematic diagram illustrating a structure of a coupling film including Mn₃Sn and MnN layers stacked by epitaxial growth.

FIG. 14 illustrates an X-ray diffraction pattern obtained from the coupling film including the Mn₃Sn and MnN layers.

FIG. 15 is a graph illustrating magnetic field dependence of Nernst coefficient of the coupling film including the Mn₃Sn and MnN layers stacked by epitaxial growth.

FIG. 16 is a graph illustrating the magnetic field dependence of Nernst coefficient of the coupling film including the Mn₃Sn and MnN layers stacked by epitaxial growth.

FIG. 17 is a graph illustrating a relation between a thickness of the Mn₃Sn layer and a bias magnetic field in the coupling film including the Mn₃Sn and NiMn layers.

FIG. 18 is a graph illustrating a relation between the thickness and coercivity of the Mn₃Sn layer in the coupling film including the Mn₃Sn and NiMn layers.

FIG. 19 is a schematic diagram illustrating a configuration of a magnetic memory device according to one specific example.

FIG. 20 is a schematic diagram illustrating manipulation of a magnetic order of the magnetoresistance element by a spin current generated in a spin Hall layer.

FIG. 21 is a schematic diagram illustrating the manipulation of the magnetic order of the magnetoresistance element by the spin current generated in the spin Hall layer.

FIG. 22 is a schematic diagram illustrating the manipulation of the magnetic order of the magnetoresistance element by the spin current generated in the spin Hall layer.

FIG. 23 is a schematic diagram illustrating the manipulation of the magnetic order of the magnetoresistance element by the spin current generated in the spin Hall layer.

FIG. 24 is a schematic diagram illustrating a configuration of a magnetic memory device according to another specific example.

FIG. 25 is a schematic diagram illustrating manipulation of a magnetic order of a magnetoresistance element by spin-transfer torque.

FIG. 26 is a schematic diagram illustrating a configuration of a photonic spin register according to one specific example.

FIG. 27 is a schematic diagram illustrating a structure of a magnetoresistance element according to another embodiment.

FIG. 28 is a schematic diagram illustrating a structure of a coupling film including Mn₃Sn and permalloy layers.

FIG. 29 is a graph illustrating a relation between a magnetic field and magnetization of permalloy when the magnetic field is applied to the coupling film including the Mn₃Sn and permalloy layers.

FIG. 30 is a graph illustrating a relation between a magnetic field and magnetization of permalloy when the magnetic field is applied to the coupling film including Mn₃Sn and permalloy layers.

FIG. 31 is a graph illustrating a relation between a magnetic field and magnetization of permalloy when the magnetic field is applied to the coupling film including the Mn₃Sn and permalloy layers.

### DESCRIPTION OF EMBODIMENTS

Hereinafter, embodiments of the present invention will be described with reference to the accompanying drawings. In the following embodiments, the same or similar components are denoted by the same reference numerals throughout the drawings. The drawings are schematic, and relations between planar dimensions and thicknesses and thickness ratios of components are different from actual ones. The dimensional relations and ratios in the drawings also differ from each other.

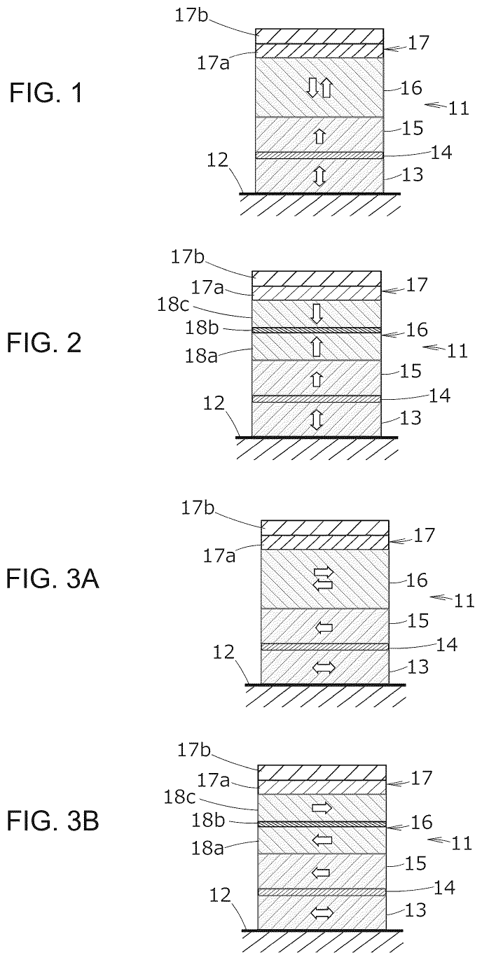

FIG. 1 schematically illustrates a structure of a magnetoresistance element according to one embodiment. A magnetoresistance element 11 includes a free layer 13 stacked on a surface of a lower electrode layer 12, a non-magnetic layer 14 stacked on the free layer 13, a pinned layer 15 stacked on the non-magnetic layer 14, and a pinning layer 16 that is stacked on the pinned layer 15 and fixes a magnetic order of the pinned layer 15 through interlayer exchange coupling. The free layer 13 is made of an antiferromagnet having a reversible magnetic order. The pinned layer 15 functions as a reference layer that establishes a fixed magnetic order with respect to the free layer 13. The magnetoresistance element 11 exhibits the greatest change in electrical resistance between the parallel and antiparallel alignments of the magnetic orders of the free layer 13 and the pinned layer 15. The magnetic orders of the free layer 13, the pinned layer 15, and the pinning layer 16 are aligned in an out-of-plane direction with respect to the interface between the layers. The lower electrode layer 12 is made of a conductor. The hollow arrows in FIG. 1 indicate directions of the magnetic orders.

An upper electrode layer 17 is stacked on the pinning layer 16. The upper electrode layer 17 is made of a conductor. The upper electrode layer 17 may include, for example, a tantalum (Ta) layer 17a stacked on the pinning layer 16 and a ruthenium (Ru) layer 17b stacked on the tantalum layer 17a. The lower electrode layer 12 and the upper electrode layer 17 can introduce an electric current into the magnetoresistance element 11.

The free layer 13 is made of an antiferromagnet having a magnetic structure with macroscopically broken time-reversal symmetry. Such antiferromagnet includes non-collinear antiferromagnets. The antiferromagnet of the free layer 13 can exhibit an anomalous Hall effect based on a chiral spin structure. Examples of the antiferromagnet include antiferromagnetic metals containing manganese (Mn), and collinear antiferromagnets having a rutile crystal structure. Examples of the antiferromagnetic metals include Mn₃X (X is one or more selected from the group consisting of Sn, Ge, Ga, Rh, Pt, and Ir), Mn₃XN (X is one or more selected from the group consisting of Ga, Sn, and Ni), and gamma-type Mn alloys having a face-centered cubic (fcc) structure. Examples of the gamma-type Mn alloys include Mn₁₋ₓFex, Mn₁₋ₓRhx, and Mn₁₋ₓPdx. Examples of the collinear antiferromagnets include RuO₂ and MngSi₃. As long as the magnetic structure with macroscopically broken time-reversal symmetry is maintained, deviations in the composition ratio and the presence of contamination can be tolerated.

The non-magnetic layer 14 is made of, for example, an insulator. Examples of the insulator include MgO, AlOx, and MgAl₂O₄. With this structure, the free layer 13, the non-magnetic layer 14, and the pinned layer 15 (reference layer) constitute a magnetic tunnel junction (MTJ). Alternatively, by using a conductive material for the non-magnetic layer 14, the magnetoresistance element 11 can also function as a giant magnetoresistance (GMR) element.

The pinned layer 15 is made of an antiferromagnet. The antiferromagnet of the pinned layer 15 has a magnetic structure with macroscopically broken time-reversal symmetry. Such antiferromagnet includes non-collinear antiferromagnets. The antiferromagnet can exhibit the anomalous Hall effect based on a chiral spin structure. Examples of the antiferromagnet include antiferromagnetic metals containing manganese (Mn), and collinear antiferromagnets having a rutile crystal structure. Examples of the antiferromagnetic metals include Mn₃X (X is one or more selected from the group consisting of Sn, Ge, Ga, Rh, Pt, and Ir), Mn XN (X is one or more selected from the group consisting of Ga, Sn, and Ni), and gamma-type Mn alloys having a face-centered cubic (fcc) structure. Examples of the gamma-type Mn alloys include Mn₁₋ₓFex, Mn₁₋ₓRhx, and Mn₁₋ₓPdx. Examples of the collinear antiferromagnets include RuO₂ and MnsSi₃. Although the pinned layer 15 and the free layer 13 are made of the same antiferromagnet, the coercivity of the pinned layer 15 is designed to be greater than that of the free layer 13 due to the effect of the pinning layer 16. As long as the magnetic structure with macroscopically broken time-reversal symmetry is maintained, deviations in the composition ratio and the presence of contamination can be tolerated.

The free layer 13 and the pinned layer 15 can be deposited separately by DC sputtering. In a chamber, the pressure is maintained at, for example, 0.5 [Pa] under an argon (Ar) atmosphere at room temperature. The power is set to 60 [W], for example. After the deposition, the free layer 13 and the pinned layer 15 are individually annealed at 500° C. for 30 minutes, for example. The annealing causes crystallization in the free layer 13 and the pinned layer 15. After the annealing, the free layer 13 and the pinned layer 15 are naturally cooled to room temperature.

The pinning layer 16 is made of a magnetically hard antiferromagnet. Such antiferromagnet may include a manganese nitride alloy (MnN), a nickel manganese alloy (NiMn), and a manganese platinum alloy (MnPt). In forming the pinning layer 16, the antiferromagnet of the pinning layer 16 is deposited at room temperature on a surface of the annealed antiferromagnet. Note that, as long as the interlayer exchange coupling is established between the pinned layer 15 and the pinning layer 16, a spacer layer may be formed between the pinned layer 15 and the pinning layer 16. The spacer layer may be made of, for example, Ru, Ir, W, Ti, a compound of the pinned layer 15, or a compound of the pinning layer 16. The inventors experimentally confirmed that the anomalous Hall effect does not occur in the antiferromagnet if the antiferromagnet of the pinned layer 15 is annealed after the deposition of the pinned layer 15 and the pinning layer 16.

In the magnetoresistance element 11 according to the present embodiment, since the free layer 13 is made of an antiferromagnet, a reversal speed of the magnetic order is higher than that of a free layer made of a ferromagnet. Therefore, the power consumption of the magnetic order reversal can be reduced in the free layer 13. In addition, since the hard magnetic order is established in the pinned layer 15 through the interlayer exchange coupling, it is possible to favorably maintain a change in the electrical resistance due to the parallel and antiparallel magnetic orders created by the free layer 13 and the pinned layer 15.

In the present embodiment, the coercivity of the pinned layer 15 is designed to be greater than that of the free layer 13. Even when the magnetic order is reversed in the free layer 13, the magnetic order can be well maintained in the pinned layer 15. Therefore, the pinned layer 15 can favorably function as the reference layer of the magnetic tunnel junction.

In the magnetoresistance element 11 according to the present embodiment, the pinned layer 15 and the free layer 13 are made of the same antiferromagnet. Even if the pinned layer 15 and the free layer 13 are made of the same material, the magnetic order of the pinned layer 15 can be well fixed due to the effect of the pinning layer 16. Therefore, the pinned layer 15 can favorably function as the reference layer of the magnetic tunnel junction.

In the present embodiment, the pinning layer 16 is made of an antiferromagnet that is magnetically harder than the antiferromagnet used in the pinned layer 15. The pinning layer 16 can favorably fix the magnetic order of the pinned layer 15. The pinned layer 15 can favorably function as the reference layer of the magnetic tunnel junction.

As shown in FIG. 2, in the pinning layer 16 of the magnetoresistance element 11, a synthetic antiferromagnet can be employed instead of the antiferromagnet described above. The synthetic antiferromagnet includes a first ferromagnetic layer 18a, a spacer layer 18b stacked on the first ferromagnetic layer, and a second ferromagnetic layer 18c stacked on the spacer layer 18b. The first ferromagnetic layer 18a is configured as a multilayer film (Co/Pt)n that is composed of n repetitions of a cobalt (Co)/platinum (Pt) bilayer. Similarly, the second ferromagnetic layer 18c is configured as a multilayer film (Co/Pt)m that is composed of repetitions of a cobalt (Co)/platinum (Pt) bilayer. Other ferromagnets such as CoFeB or CoFe may be used for these ferromagnetic layers. The spacer layer 18b is made of a metal such as ruthenium (Ru) or iridium (Ir). The spacer layer 18b is in close contact with the first ferromagnetic layer 18a and the second ferromagnetic layer 18c. The magnetic orders of the free layer 13, the pinned layer 15, and the pinning layer 16 are aligned in an out-of-plane direction with respect to the interface between the layers. In addition, as shown in FIGS. 3A and 3B, the magnetic orders of the free layer 13, the pinned layer 15, and the pinning layer 16 may be aligned in an in-plane direction with respect to the interface between the layers. The hollow arrows in FIGS. 1 to 3B indicate the directions of the magnetic orders.

In the embodiment, the pinning layer 16 is made of a magnetically hard synthetic antiferromagnet. The pinning layer 16 can favorably fix the magnetic order of the pinned layer 15. The pinned layer 15 can favorably function as the reference layer of the magnetic tunnel junction.

The inventors conducted experiments to investigate the interlayer exchange coupling between the pinned layer 15 and the pinning layer 16. In the experiments, the inventors prepared a coupling film including a Mn₃Sn layer [thickness: 30 nm] and a NiMn layer [thickness: 20 nm]. The Mn₃Sn layer was deposited at room temperature on a SiO₂/Si substrate using DC sputtering. The pressure inside a chamber was maintained at 0.5 [Pa] under an argon (Ar) atmosphere. The power was set to 60 [W].

After the deposition, the Mn₃Sn layer was annealed at 500° C. for 30 minutes in vacuum. The Mn₃Sn layer was crystallized by annealing. After natural cooling to room temperature, the NiMn layer [thickness: 20 nm] was deposited on the Mn₃Sn layer. Co-evaporation of Mn from a K-cell and Ni from an E-gun was carried out. The vacuum level was set to 1×10⁻⁶ [Pa]. The evaporation rate of Ni was set to 0.13 [angstroms/s]. The evaporation rate of Mn was set to 0.15 [angstroms/s].

Then, an AlOₓ layer as a capping layer with a thickness of 5 [nm] was deposited on the NiMn layer using RF sputtering. The pressure inside a chamber was maintained at 0.2 [Pa] under an argon (Ar) atmosphere. The RF power was set to 100 [W]. The deposition rate was set to 1.6 [nm/min].

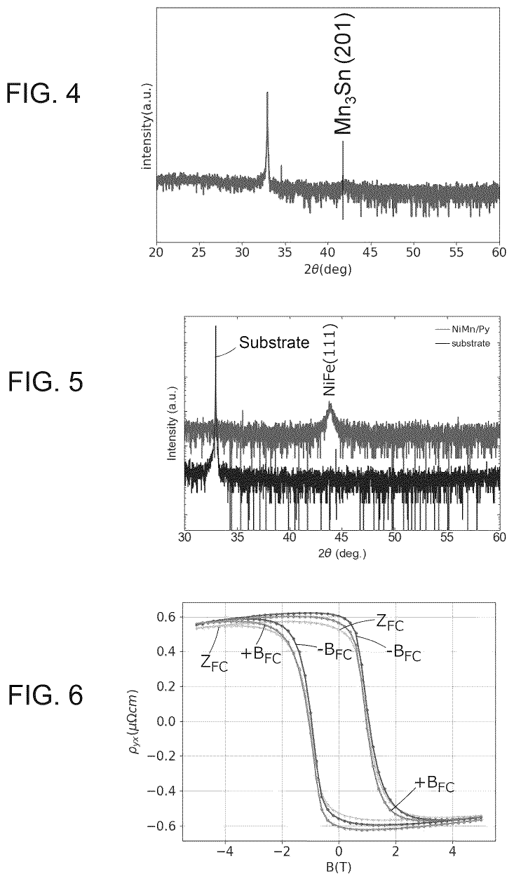

The inventors observed a crystal structure of the coupling film using X-ray diffraction. As shown in FIG. 4, a Mn3Sn peak was observed. On the other hand, no NiMn peak was observed. The inventors prepared a comparative example to evaluate the interlayer exchange coupling. In the comparative example, a multilayer film including a permalloy layer (Ni_{0.8}Fe_{0.2}) [thickness: 50 nm] and a NiMn layer [thickness: 20 nm] was prepared. The permalloy layer [thickness: 50 nm] and the NiMn layer [thickness: 20 nm] were sequentially deposited at room temperature on a SiO₂/Si substrate. An E-gun was used for the deposition of the permalloy layer. Then, the NiMn layer [thickness: 20 nm] and the AlOx layer with a thickness of 5 [nm] were deposited in the same manner as described above. As shown in FIG. 5, by X-ray diffraction, a permalloy peak (111) was observed, but no NiMn peak was observed.

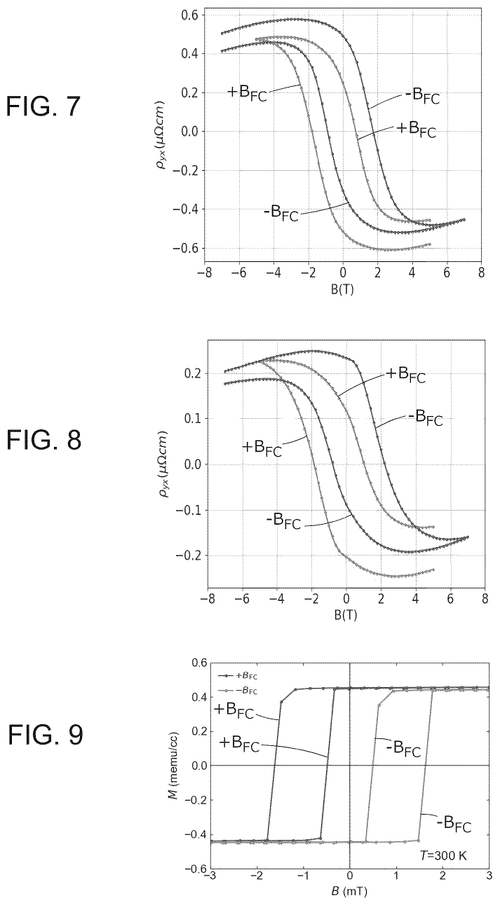

The inventors evaluated the magnetic coupling of the NiMn/Mn₃Sn coupling film based on the measurement of the anomalous Hall effect. As shown in FIG. 6, the anomalous Hall effect with a coercivity Hc of 1 [T] was observed in the Mn₃Sn layer. The coupling film was naturally cooled from 400 [K] to 300 [K] under an out-of-plane magnetic field of B_{FC}=+5 [T]. The +B_{FC}loop is shifted toward a negative magnetic field direction, indicating the presence of the exchange bias [Hₑₓ=0.047 T]. The −B_{FC} loop is shifted toward a positive direction by approximately the same shift amount, indicating the presence of the exchange bias. The interface coupling energy is calculated to be J=0.016 [mJ/m²]. As shown in FIGS. 7 and 8, cooling the coupling film to 200 [K] or 100 [K] reveals the presence of a significantly larger exchange bias [Hₑₓ=0.5 T].

The inventors evaluated the magnetic coupling of the multilayer film of the comparative example based on magnetization measurement. Oven option of MPMS was used for the measurement. As shown in FIG. 9, a shift of about 1 [mT] was observed in an M-H curve. The multilayer film was naturally cooled from 600 [K] to 300 [K] under an out-of-plane magnetic field of o BFC=0.05 [T]. The interface coupling energy is calculated to be J=0.036 [mJ/m²].

Next, the inventors prepared a coupling film including a Mn₃Sn layer [thickness: 35 nm] and a MnN layer [thickness: 30 nm]. The Mn₃Sn layer was deposited at room temperature on a SiO₂/Si substrate using DC sputtering. The pressure inside a chamber was maintained at 0.5 [Pa] under an argon (Ar) atmosphere. The power was set to 60 [W].

After the deposition, the Mn₃Sn layer was annealed at 500° C. for 30 minutes in vacuum. The Mn₃Sn layer was crystallized by annealing. After natural cooling to room temperature, the MnN layer [thickness: 30 nm] was deposited on the Mn₃Sn layer using reactive sputtering. The flow rate of nitrogen gas was set to 60% of the total amount of argon gas and nitrogen gas. The pressure of the argon gas was set to 0.5 [Pa]. The deposition rate was set to 1.6 [nm/min].

Then, an Al₂O₃ layer as a capping layer with a thickness of 3 [mm] was deposited on the MAN layer using RF sputtering. The pressure inside a chamber was maintained at 0.2 [Pa] under an argon (Ar) atmosphere. The RF power was set to 100 [W]. The deposition rate was set to 1.6 [nm/min].

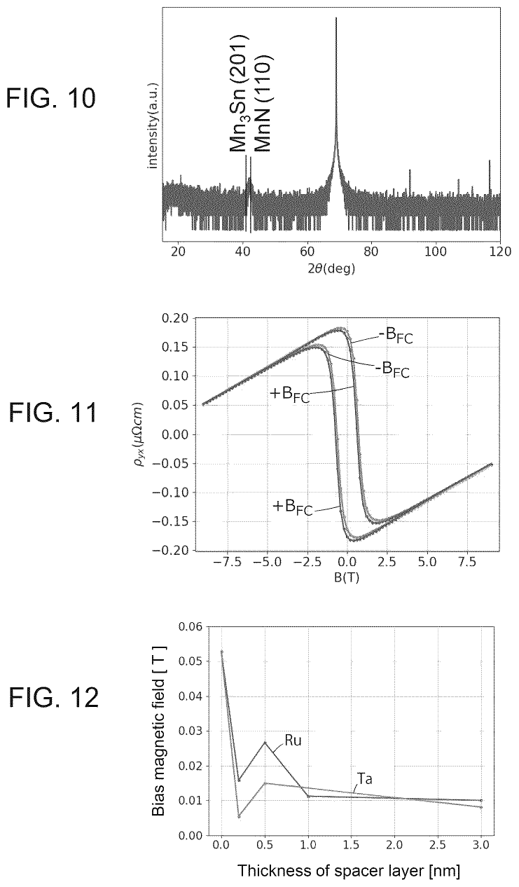

The inventors observed a crystal structure of the coupling film using X-ray diffraction. As shown in FIG. 10, a Mn₃Sn peak (201) and a MnN peak (110) were observed. As described above, the magnetic coupling of the MnN/Mn₃Sn coupling film was v evaluated based on the measurement of the anomalous Hall effect. As shown in FIG. 11, the anomalous Hall effect with a coercivity Hc of 0.6 [T] was observed in the Mn₃Sn layer. The coupling film was naturally cooled from 400 [K] to 300 [K] under an out-of-plane magnetic field of B_{FC}=+5 [T]. The +B_{FC} loop is shifted toward a negative magnetic field direction, indicating the presence of the exchange bias [Hₑₓ=0.057 T]. Th −B_{FC} loop is shifted toward a positive direction by approximately the same shift amount, indicating the presence of the exchange bias. The interface coupling energy is calculated to be J=0.018 [mJ/m²].

The inventors conducted experiments to investigate the exchange bias caused by the MnN layer. In the experiments, a non-magnetic spacer layer was provided between the Mn₃Sn layer [thickness: 35 nm] and the MnN layer [thickness: 30 nm]. Tantalum (Ta) or ruthenium (Ru) was used for the spacer layer. The exchange bias was observed depending on a thickness of the spacer layer. FIG. 12 reveals that the exchange bias decreases due to the interposition of the spacer layer. This confirms that MnN is responsible for the exchange bias effect.

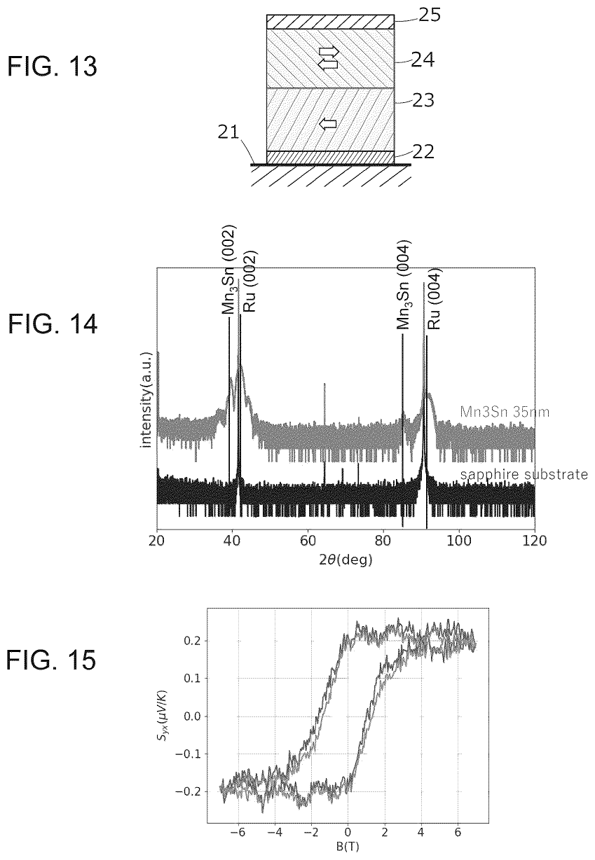

Next, the inventors tried to improve the interface roughness and crystallinity of the coupling film including the Mn₃Sn layer [thickness: 35 nm] and the MnN layer [thickness: 30 nm]. The inventors employed epitaxial growth of the Mn₃Sn layer to improve the interface roughness and crystallinity. As shown in FIG. 13, a non-magnetic underlayer 22 was formed on a substrate 21. For example, ruthenium (Ru) was used for the underlayer 22. The underlayer 22 was formed to have a thickness of 5 [nm]. A sapphire (0001) substrate was used as the substrate 21.

DC sputtering was used for the deposition. The pressure inside a chamber was maintained at 1.0 [Pa] under an argon (Ar) atmosphere. The power was set to 50 [W]. The deposition rate was set to 2 [nm/min]. The substrate 21 was heated to 700° C. The (0001)-oriented ruthenium underlayer 22 was obtained by annealing for 60 minutes. Then, the substrate 21 and the underlayer 22 were naturally cooled to room temperature.

After the cooling, a Mn₃Sn layer 23 was deposited at room temperature on the underlayer 22 using DC sputtering. The pressure inside a chamber was maintained at 0.5 [Pa] under an argon (Ar) atmosphere. The power was set to 50 [W]. The deposition rate was set to 3 [nm/min].

After the deposition, the Mn₃Sn layer 23 was annealed at 340° C. for 20 minutes in vacuum. The Mn₃Sn layer 23 was crystallized by annealing. Epitaxial growth of Mn₃Sn crystal grains was achieved due to the (0001) orientation of the underlayer 22. After natural cooling to room temperature, a MnN layer 24 [thickness: 30 nm] was deposited on the Mn₃Sn layer 23 using reactive sputtering. The flow rate of nitrogen gas was set to 60% of the total amount of argon gas and nitrogen gas. The pressure of the argon gas was set to 0.5 [Pa]. Then, an Al₂O₃ layer as a capping layer with a thickness of 5 [mm] was deposited on the NiMn layer 24 using RF sputtering.

The inventors observed a crystal structure of the coupling film using X-ray diffraction. As shown in FIG. 14, Mn₃Sn peaks (002) and (004) as well as Ru peaks (002) and (004) were observed, which confirms the epitaxial growth of the Mn₃Sn layer.

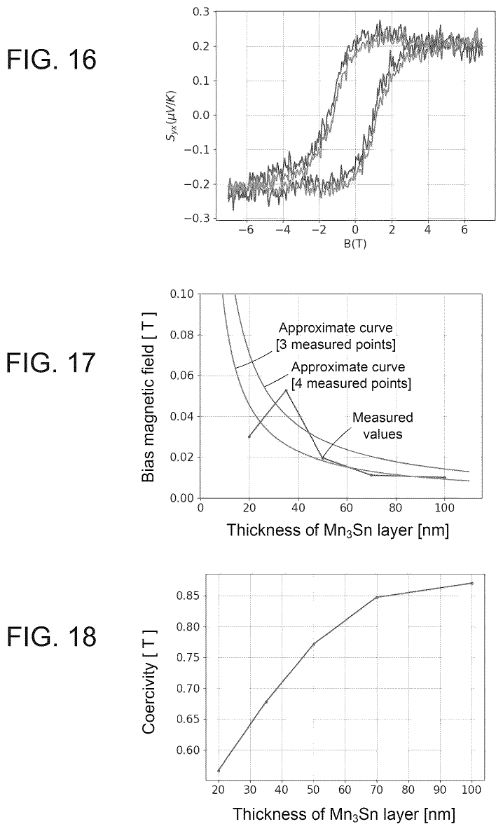

The magnetic coupling of the MnN/Mn₃Sn coupling film was evaluated based on the measurement of an anomalous Nernst effect. As shown in FIG. 15, in the first loop, the anomalous Hall effect with a coercivity Hc of 1.37 [T] was observed in the Mn₃Sn layer. The coupling film was naturally cooled from 400 [K] to 300 [K] under an in-plane magnetic field of B_{FC}=0.8 [T]. The B_{FC} loop is shifted toward a negative magnetic field direction, indicating the presence of the exchange bias [Hₑₓ=0.27 T]. The −B_{FC} loop is shifted toward a positive direction by approximately the same shift amount, indicating the presence of the exchange bias. The interface coupling energy is calculated to be J=0.085 [mJ/m²]. As shown in FIG. 16, in the third loop, the coercivity Hc of the Mn₃Sn layer decreases to 1.22 [T] due to a training effect. The exchange bias Hₑₓ decreases to 0.20 [T].

The inventors observed the bias magnetic field of the Mn₃Sn layer 23 in the MnN/Mn₃Sn coupling film. The inventors changed the thickness of the Mn₃Sn layer 23. The anomalous Hall effect and shift in the magnetic field direction were observed in all thicknesses. As shown in FIG. 17, in a range of 50 nm≤thickness t≤100 nm, an approximate curve as a function of 1/t is calculated from three measured values, which confirms that the bias magnetic field decreases as the thickness increases. Similarly, an approximate curve as a function of 1/t is calculated from four measured values in a range of 35 nm≤thickness t≤100 nm, which confirms that the bias magnetic field decreases as the thickness increases. It is presumed that the reduction in bias magnetic field at a thickness of 20 nm is attributable to a deterioration in crystallinity. As shown in FIG. 18, it can be seen that the coercivity increases as the thickness of the Mn₃Sn layer increases.

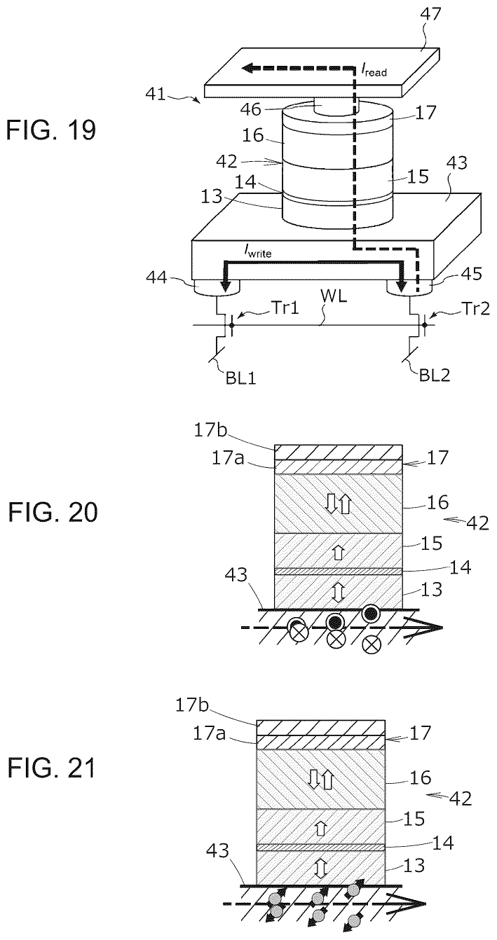

FIG. 19 schematically illustrates a configuration of a magnetic memory device according to one specific example. A magnetic memory device 41 includes a magnetoresistance element 42 that reverses a magnetic order of a free layer 13 made of an antiferromagnet to change the electrical resistance, and a spin Hall layer 43 that is in contact with the free layer 13 of the magnetoresistance element 42 and through which an electric current flows parallel to an interface with the free layer 13. Similarly to the magnetoresistance element 11 described above, the magnetoresistance element 42 includes the free layer 13 stacked on a surface of the spin Hall layer 43, a non-magnetic layer 14 stacked on the free layer 13, a pinned layer 15 stacked on the non-magnetic layer 14, and a pinning layer 16 that is stacked on the pinned layer 15 and fixes a magnetic order of the pinned layer 15 through the interlayer exchange coupling. The free layer 13 is made of an antiferromagnet having a reversible magnetic order. The pinned layer 15 functions as a reference layer that establishes a fixed magnetic order with respect to the free layer 13. When the magnetic order of the free layer 13 is parallel to the magnetic order of the pinned layer 15, the magnetoresistance element 42 exhibits a low electrical resistance. When the magnetic order of the free layer 13 is antiparallel to the magnetic order of the pinned layer 15, the magnetoresistance element 42 exhibits a high electrical resistance. The magnetic orders of the free layer 13, the pinned layer 15, and the pinning layer 16 are aligned in an out-of-plane direction with respect to the interface between the layers. The spin Hall layer 43 is made of a material exhibiting a spin Hall effect (hereinafter, referred to as “spin Hall material”). Examples of the spin Hall material include non-magnetic heavy metals, topological insulators, topological semimetals, and topological magnets. Examples of the non-magnetic heavy metals include tantalum (Ta), tungsten (W), and platinum (Pt). Examples of the topological insulators include bismuth tellurium (BiTe), bismuth antimony (BiSb), and bismuth antimony tellurium (BiSbTe). Examples of the topological semimetals include tungsten telluride (WTe₂) and molybdenum telluride (MoTe₂). Examples of the topological magnets include Mn₃X (X is one or more elements selected from the group consisting of Sn, Ge, Ga, Rh, Pt, and Ir), cobalt-manganese-gallium (Co₂MnGa), iron-gallium (Fe₃Ga), and iron-aluminum (Fe₃Al). When an electric current I_{write} flows through the spin Hall layer 43 in parallel to the interface with the free layer 13, a spin current is generated in an out-of-plane direction (z direction) due to the spin Hall effect, and a spin-orbit torque (SOT) acts on the magnetic order (magnetization) of the free layer 13, thereby reversing the magnetic order.

The magnetic memory device 41 includes a first terminal 44 and a second terminal 45 that are connected to the spin Hall layer 43 and introduce a predetermined electric current into the spin Hall layer 43. The first terminal 44 and the second terminal 45 are made of, example, a conductive metal material. The first terminal 44 and the second terminal 45 are disposed apart from each other. A first transistor element Tr1 is connected to the first terminal 44. A second transistor element Tr2 is connected to the second terminal 45. The direction of the electric current between the first terminal 44 and the second terminal 45 can be selectively controlled by the operation of the first transistor element Tr1 and the second transistor element Tr2.

The first transistor element Tr1 includes, for example, a negative-channel metal oxide semiconductor (NMOS) field effect transistor. The first transistor element Tr1 includes a drain connected to the first terminal 44, a source connected to a first bit line BL1, and a gate connected to a word line WL. Similarly, the second transistor element Tr2 includes, for example, an NMOS field effect transistor. The second transistor element Tr2 includes a drain connected to the second terminal 45, a source connected to a second bit line BL2, and a gate connected to the word line WL. When the electric potential of the first bit line BL1 is higher than that of the second bit line BL2, the electric current flows from the first terminal 44 to the second terminal 45. Conversely, when the electric potential of the second bit line BL2 is higher than that of the first bit line BL1, the electric current flows from the second terminal 45 to the first terminal 44.

The magnetic memory device 41 includes a third terminal 46 that is connected to the upper electrode layer 17 of the magnetoresistance element 42 and introduces an electric current into the magnetoresistance element 42 in an out-of-plane direction. The third terminal 46 is made of, for example, a conductive metal material. The third terminal 46 is connected to a ground line 47 at ground potential. With this structure, the electric current can flow from the first terminal 44 or the second terminal 45 to the third terminal 46.

Next, an operation of the magnetic memory device 41 will be described. Initially, a non-magnetic heavy metal is assumed to be used for the spin Hall layer 43. The magnetic order of the free layer 13 is switched between parallel and antiparallel alignments with respect to the magnetic order of the pinned layer 15. When the magnetic order of the free layer 13 is parallel to the magnetic order of the pinned layer 15, the magnetoresistance element 42 exhibits a low electrical resistance. When the magnetic order of the free layer 13 is antiparallel to the magnetic order of the pinned layer 15, the magnetoresistance element 42 exhibits a high electrical resistance. Binary information can be distinguished based on whether the magnetoresistance element 42 is in a low-resistance or high-resistance state. Data values of “1” and “0” are assigned to the parallel and antiparallel magnetic orders, respectively. Because the parallel or antiparallel magnetic order is maintained without the application of voltage, data can be maintained in the magnetic memory device 41 without power supply.

To write data, the electric current I_{write} is supplied from the first terminal 44 and the second terminal 45 to the spin Hall layer 43. When a high-level voltage signal is supplied to the word line WL, a voltage equal to or greater than a threshold is applied to the gate of the first transistor element Tr1 and the gate of the second transistor element Tr2. When the first bit line BL1 is set to a high level and the second bit line BL2 is set to a low level, the electric current I_{write} is introduced from the first terminal 44 to the spin Hall layer 43 and flows from the second terminal 45 into the second bit line BL2. As shown in FIG. 20, when the electric current flows through the spin Hall layer 43 in an in-plane direction, a spin current is generated in an out-of-plane direction due to the spin Hall effect, and the magnetic order of the free layer 13 is governed by SOT. For example, a parallel magnetic order is established between the free layer 13 and the pinned layer 15. When the second bit line BL2 is set to a high level and the first bit line BL1 is set to a low level, the electric current is introduced from the second terminal 45 to the spin Hall layer 43 and flows from the first terminal 44 into the first bit line BL1. SOT enables the establishment of an antiparallel magnetic order between the free layer 13 and the pinned layer 15.

In the magnetic memory device 41 according to the present embodiment, since the free layer 13 of the magnetoresistance element 42 is made of an antiferromagnet, a reversal speed of the magnetic order is higher than that of a free layer made of a ferromagnet. Therefore, in the free layer 13, power consumption associated with the magnetic order reversal can be reduced. In addition, since a hard magnetic order is established in the pinned layer 15 through the interlayer exchange coupling, it is possible to favorably maintain a change in the electrical resistance.

To read data, for example, an electric current I_{read} is supplied from the second terminal 45 to the magnetoresistance element 42. When a high-level voltage signal is supplied to the word line WL, and when the first bit line BL1 is opened and the second bit line BL2 is set to a high level, the electric current I_{read} flows from the second terminal 45 to the third terminal 46. The electric current I_{read} is affected by the electrical resistance of the magnetoresistance element 42. Since data values of “1” and “0” are assigned to high-resistance and low-resistance values, respectively, the value of “1” or “0” can be determined by measuring the magnitude of the electric current I_{read}.

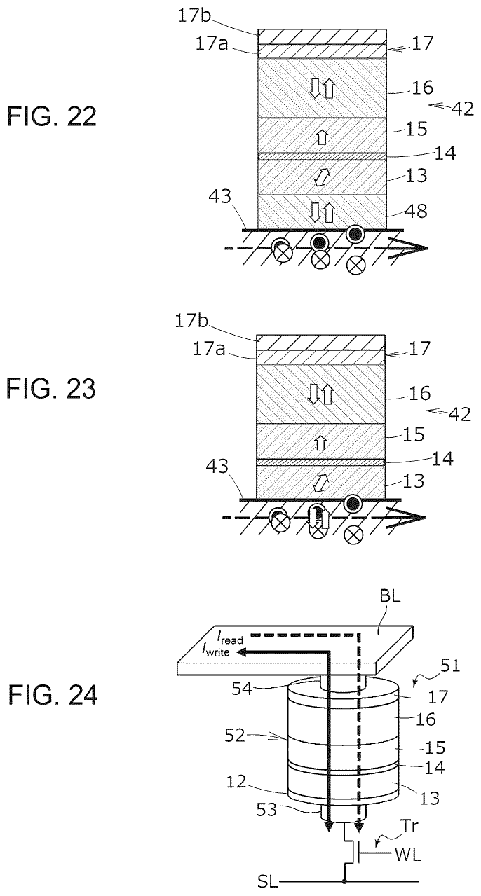

In the spin Hall layer 43 of the magnetic memory device 41, a topological insulator, a topological semimetal, or a topological magnet can be used instead of a non-magnetic metal. In this case, as shown in FIG. 21, when an electric current flows through the spin Hall layer 43 in one direction parallel to the in-plane direction, electrons that are spin-polarized either parallel or obliquely with respect to the out-of-plane direction are scattered toward the upper side (free layer 13 side) and the lower side of the spin Hall layer 43, thereby generating spin accumulation. The spin polarization direction of the spin accumulation on the upper side of the spin Hall layer 43 is opposite to the spin polarization direction of the spin accumulation on the lower side. The spin current thus generated in the out-of-plane direction induces SOT. In addition, as shown in FIG. 22, an antiferromagnetic layer 48 may be provided between the spin Hall layer 43 and the free layer 13. The antiferromagnetic layer 48 is made of, for example, NiMn, MnN, MnPt, MnIr, or FeNi. The antiferromagnetic layer 48 can tilt the magnetic order in the free layer 13 with respect to the out-of-plane direction. Accordingly, the magnetic order in the free layer 13 can be readily reversed by the SOT acting in the out-of-plane direction. As shown in FIG. 23, an antiferromagnet may be used for the spin Hall layer 43. Examples of the antiferromagnet of the spin Hall layer 43 include NiMn, MnN, MnPt, MnIr, and FeNi. Such a spin Hall layer 43 can tilt the magnetic order in the free layer 13 with respect to the out-direction.

FIG. 24 schematically illustrates a configuration of a magnetic memory device according to another specific example. A magnetic memory device 51 includes a magnetoresistance element 52 that reverses a magnetic order of a free layer 13 made of an antiferromagnet to change the electrical resistance, and a first terminal 53 and a second terminal 54 that introduce an electric current into the free layer 13 of the magnetoresistance element 52 in an out-of-plane direction. Similarly to the magnetoresistance element 11 described above, the magnetoresistance element 51 includes the free layer 13 stacked on a surface of a lower electrode layer 12, a non-magnetic layer 14 stacked on the free layer 13, a pinned layer 15 stacked on the non-magnetic layer 14, and a pinning layer 16 stacked on the pinned layer 15 to fix the magnetic order of the pinned layer 15 through the interlayer exchange coupling. The free layer 13 is made of an antiferromagnet having a reversible magnetic order. The pinned layer 15 functions as a reference layer that establishes a fixed magnetic order with respect to the free layer 13. When the magnetic order of the free layer 13 is parallel to the magnetic order of the pinned layer 15, the magnetoresistance element 52 exhibits a low electrical resistance. When the magnetic order of the free layer 13 is antiparallel to the magnetic order of the pinned layer 15, the magnetoresistance element 52 exhibits a high electrical resistance. The magnetic orders of the free layer 13, the pinned layer 15, and the pinning layer 16 are aligned in an out-of-plane direction with respect to the interface between the layers.

The first terminal 53 and the second terminal 54 are made of, for example, a conductive metal material. The first terminal 44 is connected to, for example, the lower electrode layer 12. The second terminal 45 is connected to, for example, the upper electrode layer 17. A transistor element Tr is connected to the first terminal 44. A bit line BL is connected to the second terminal 45. By the operation of the transistor element Tr, whether an electric current flows between the first terminal and the second terminal can be controlled.

The transistor element Tr includes, for example, an NMOS field effect transistor. The transistor element Tr includes a drain connected to the first terminal 53, a source connected to a source line SL, and a gate connected to a word line WL. When a high-level voltage is applied to the gate from the word line WL, the electric current flows between the bit line BL and the source line.

Next, an operation of the magnetic memory device 51 will be described. The magnetic order of the free layer 13 can be switched between parallel and antiparallel alignments with respect to the magnetic order of the pinned layer 15. When the magnetic order of the free layer 13 is parallel to the magnetic order of the pinned layer 15, the magnetoresistance element 52 exhibits a low electrical resistance. When the magnetic order of the free layer 13 is antiparallel to the magnetic order of the pinned layer 15, the magnetoresistance element 52 exhibits a high electrical resistance. Binary information can be distinguished based on whether the magnetoresistance element 52 is in a low-resistance or high-resistance state. Data values of “1” and “0” are assigned to the parallel and antiparallel magnetic orders, respectively. Because the parallel or antiparallel magnetic order is maintained without the application of voltage, data can be maintained in the magnetic memory device 51 without power supply.

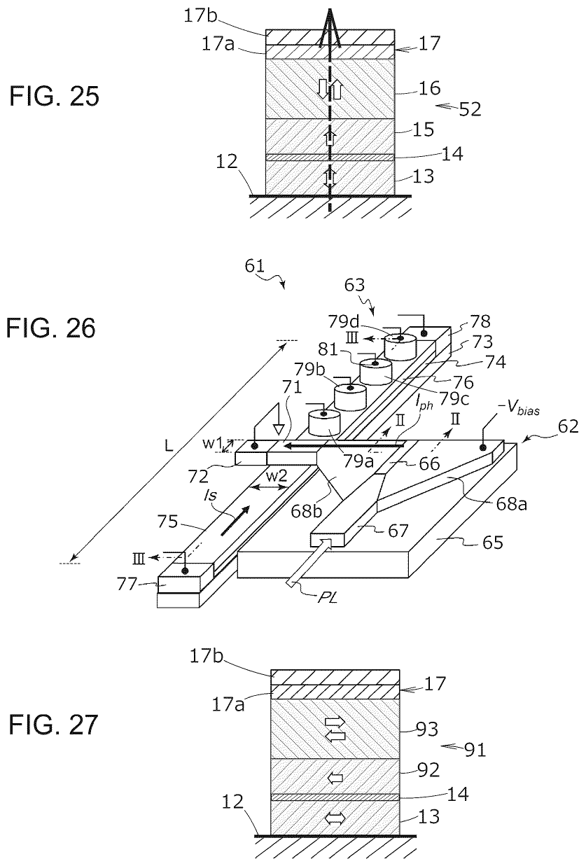

To write data, an electric current I_{write} is supplied from the first terminal 53 and the second terminal 54 to the magnetoresistance element 52. When a high-level voltage signal is supplied to the word line WL, a voltage equal to or greater than a threshold is applied to the gate of the transistor element Tr. When the bit line BL is set to a high level and the source line SL is set to a low level, the electric current I_{write} is introduced from the second terminal 54 into the magnetoresistance element 52 and flows from the first terminal 53 into the source line SL. On the other hand, when the source line SL is set to a high level and the bit line BL is set to a low level, the electric current I_{write} is introduced from the first terminal 53 into the magnetoresistance element 52 and flows from the second terminal 54 into the bit line BL. As shown in FIG. 25, when the electric current flows through the free layer 13 in an out-of-plane direction, the magnetic order of the free layer 13 is governed by spin-transfer torque (STT), and data can be written. The data to be written can be changed depending on the direction of the electric current I_{write}. In this way, the parallel magnetic order or the antiparallel magnetic order is established between the free layer 13 and the pinned layer 15.

In the magnetic memory device 51 according to the present embodiment, since the free layer 13 of the magnetoresistance element 52 is made of an antiferromagnet, a reversal speed of the magnetic order is higher than that of a free layer made of a ferromagnet. Therefore, in the free layer 13, the power consumption associated with the magnetic order reversal can be reduced. In addition, since a hard magnetic order is established in the pinned layer 15 through the interlayer exchange coupling, it is possible to favorably maintain a change in the electrical resistance.

To read data, for example, an electric current I_{read} is supplied from the second terminal 54 to the magnetoresistance element 52. When a high-level voltage signal is supplied to the word line WL, and when the bit line BL is set to a high level and the source line SL is set to a low level, the electric current I_{read} flows from the second terminal 54 to the first terminal 53. The electric current I_{read} is affected by the electrical resistance of the magnetoresistance element 52. Since data values of “1” and “0” are assigned to high-resistance and low-resistance values, respectively, the value of “1” or “0” can be determined by measuring the magnitude of the electric current I_{read}.

The magnetic memory devices 41 are arranged in a matrix to constitute, for example, a cache memory. Such a cache memory can be connected to, for example, a processor (MPU or CPU) and used in an information processing system such as a computer system. Similarly, the magnetic memory devices 51 can be arranged in a matrix to constitute, for example, a cache memory.

The magnetoresistance element of the present embodiment is applicable to a photonic spin register disclosed in WO2022/158545. FIG. 26 schematically illustrates a configuration of a photonic spin register 61. The photonic spin register 61 includes a light receiver 62 that generates an electrical signal of serial data from an optical signal PL of the serial data, and a shift register 63 that is connected to the light receiver 62 and generates an electrical signal of parallel data from the electrical signal of the serial data. The optical signal PL carries the serial data based on pulse-amplitude modulation.

The light receiver 62 includes a substrate 65 made of an insulator, a photoelectric conversion element 66 that is provided on the substrate 65 and outputs an electrical signal in response to the received optical signal PL, and an optical waveguide 67 that is provided on the substrate 65 and guides the optical signal PL toward the photoelectric conversion element 66. For example, SiO₂ is used for the insulator. The photoelectric conversion element 66 is made of a dielectric (semiconductor or insulator). On the substrate 65, the photoelectric conversion element 66 is sandwiched between metal films 68a and 68b stacked on the substrate 65. The photoelectric conversion element 66 is in close contact with the metal films 68a and 68b at the respective interfaces as a result of being sandwiched. The metal films 68a and 68b are made of a metal material such as Au or Ag. The metal films 68a and 68b constitute a plasmon waveguide.

The optical waveguide 67 is gradually tapered toward the photoelectric conversion element 66. The narrower the width of the photoelectric conversion element 66 is (e.g., 50 nm), the greater the light confinement effect becomes, which makes it possible to focus light to a smaller area than a diffraction limitation and enhance the interaction between the photoelectric conversion element 66 and an optical electric field. This leads to an increased light absorptivity, achieving a responsivity of about 1 [A/W] in an element length of 1 [μm] to 2 [μm].

The light receiver 62 includes a spin Hall element 71 that is connected to the metal film 68b and disposed on the shift register 63. The spin Hall element 71 is made of a spin Hall material, similar to the spin Hall layer 43 described above. An electrode 72 is connected on the opposite side of the spin Hall element 71 from the metal film 68b. The electrode 72 is grounded. When a bias voltage V_{bias} is applied to the metal film 68a, a photocurrent Iₚₕ flows into the spin Hall element 71 across the photoelectric conversion element 66. When the photocurrent flows through the spin Hall element 71 parallel to an interface with the shift register 63, a spin current is generated in an out-of-plane direction due to the spin Hall effect.

The shift register 63 includes a substrate 73, an elongated spin Hall layer 74 that is stacked on the substrate 73 and extends linearly, a first magnetic layer 75 that is stacked on the spin Hall layer 74 and extends linearly from one end of the spin Hall layer 74 toward the other end, and a second magnetic layer 76 that is stacked on the spin Hall layer 74, is connected in series with the first magnetic layer 75 in the linear direction, and extends to the other end of the spin Hall layer 74. The spin Hall layer 74 is made of a spin Hall material, similar to the spin Hall layer 43 described above. In the first magnetic layer 75 and the second magnetic layer 76 which are linearly arranged in succession, a series of magnetic domains separated by domain walls are arranged in a line along the linear direction. The first magnetic layer 75 and the second magnetic layer 76 are made of, for example, a topological antiferromagnet such as Mn₃X (X is one or more selected from the group consisting of Sn, Ge, Ga, Rh, Pt, and Ir), or a ferrimagnet (e.g., GdFeCo). As long as the magnetic structure with macroscopically broken time-reversal symmetry is maintained, deviations in the composition ratio and the presence of contamination can be tolerated. The spin Hall layer 74 has, for example, a thickness of 4 [nm], and the first magnetic layer 75 and the second magnetic layer 76 have, for example, a thickness of 6 [nm]. In the first magnetic layer 75, a magnetic order is fixed by, for example, a magnet in an out-of-plane direction with respect to an interface with the spin Hall layer 74. The spin Hall element 71 is stacked on a magnetic domain in the first magnetic layer 75 such that the magnetic domain is adjacent to the second magnetic layer 76.

A first electrode 77 is connected to the spin Hall layer 74 and the first magnetic layer 75 at the one end of the spin Hall layer 74. A second electrode 78 is connected to the spin Hall layer 74 and the second magnetic layer 76 at the other end of the spin Hall layer 74. A shift current Iₛ which is a direct current flows from the first electrode 77 to the second electrode 78. The shift current Iₛ induces the motion of the domain walls in the first magnetic layer 75 and the second magnetic layer 76. In the domain wall motion, the direction of the magnetic order is maintained in each magnetic domain.

A plurality of read elements 79a, 79b, 79c, and 79d are arranged in a line along the linear direction on the second magnetic layer 76. Each of the read elements 79a, 79b, 79c, and 79d includes a barrier layer made of a non-magnetic material (e.g., MgO) stacked on the second magnetic layer 76, a pinned layer 15 stacked on the barrier layer, a pinning layer 16 that is stacked on the pinned layer 15 and fixes a magnetic order of the pinned layer 15 through the interlayer exchange coupling, and an upper electrode layer 17 stacked on the pinning layer 16. An output terminal 81 is connected to the upper electrode layer 17. The second magnetic layer 76 is made of an antiferromagnet having a reversible magnetic order for each magnetic domain. The magnetic domains are respectively combined with the read elements 79a, 79b, 79c, and 79d to constitute the magnetoresistance elements 11. Each magnetic domain functions as the free layer 13.

Next, an operation of the photonic spin register 61 will be described. In the following description, it is assumed that the magnetic order of the first magnetic layer 75 is preset to be fixed in the downward direction, and the magnetic order of the pinned layer 15 in each of the read elements 79a, 79b, 79c, and 79d is fixed in the upward direction. When the magnetic order of the magnetic domain in contact with one of the read elements 79a, 79b, 79c, and 79d is parallel to the magnetic order of the pinned layer 15 of the one of the read elements 79a, 79b, 79c, and 79d, the value “1” is specified. When the magnetic order of the magnetic domain in contact with one of the read elements 79a, 79b, 79c, and 79d is antiparallel to the magnetic order of the pinned layer 15 of the one of the read elements 79a, 79b, 79c, and 79d, the value “0” is specified.

The optical signal PL is guided by the optical waveguide 67 and input into the photoelectric conversion element 66. The optical signal PL carries serial data based on the pulse-amplitude modulation. The optical signal PL propagates in the form of a surface plasmon polariton at interfaces between the photoelectric conversion element 66 and the metal films 68a and 68b, producing a strong electric field in the surrounding area. When the bias voltage V_{bias} is applied, the photocurrent Iₚₕ flows from the photoelectric conversion element 66 to the spin Hall element 71.

When the photocurrent Iₚₕ flows through the spin Hall element 71 parallel to an interface with the first magnetic layer 75, a spin current is generated in the spin Hall element 71 in the out-of-plane direction. SOT acts on the magnetic order in the first magnetic layer 75 that is in contact with the spin Hall element 71. Because the photocurrent Iₚₕ is a pulsed current corresponding to the values “1” and “0” included in the optical signal PL, the magnetic order of the magnetic domain in the first magnetic layer 75 is reversed when a current density of the photocurrent Iₚₕ is equal to or greater than a threshold in a pulse width duration. When the current density of the photocurrent Iₚₕ does not reach the threshold, the magnetic order reversal does not occur. In this way, the values “1” and “0” included in the optical signal PL can be transferred to a spin state of the magnetic domain by means of the photocurrent Iₚₕ.

When the shift current Iₛ flows through the spin Hall layer 74, the domain walls in the first magnetic layer 75 and the second magnetic layer 76 move in the direction of the shift current Iₛ due to SOT. The magnetic order established by the action of the spin Hall element 71 moves sequentially through the positions of the read elements 79a, 79b, 79c, and 79d. The magnetic domain in an initial state move to the position of the spin Hall element 71. By repeating this operation, the serial data of the optical signal PL can be written into the second magnetic layer 76. The read elements 79a, 79b, 79c, and 79d are respectively combined with the corresponding magnetic domains in the second magnetic layer 76 to establish magnetic tunnel junctions.

When a voltage is applied to the second magnetic layer 76 and the read elements 79a, 79b, 79c, and 79d for each of the read elements 79a, 79b, 79c, and 79d, a read current is generated in an out-of-plane direction for each of the read elements 79a, 79b, 79c, and 79d. The read current is output from the output terminal 81. The magnitude of the read current changes depending on the electrical resistance determined based on the magnetoresistance effect of the magnetic tunnel junction. Therefore, the value “1” or “0” can be determined for each of the read elements 79a, 79b, 79c, and 79d. In this way, the optical signal of the serial data can be converted into the electrical signal of the parallel data.

FIG. 27 schematically illustrates a configuration of a magnetoresistance element according to another embodiment. A magnetoresistance element 91 includes a free layer 13 stacked on a surface of a lower electrode layer 12, a non-magnetic layer 14 stacked on the free layer 13, a pinned layer 92 that is stacked on the non-magnetic layer 14 and made of a ferromagnet, and a pinning layer 93 that is stacked on the pinned layer 92 and fixes a magnetic order of the pinned layer 92 through the interlayer exchange coupling. The lower electrode layer 12 is made of a conductor. The free layer 13 is made of an antiferromagnet having a reversible magnetic order. The free layer 13 and the non-magnetic layer 14 are configured in the Same manner as described above. The pinned layer 92 functions as a reference layer that establishes a fixed magnetic order with respect to the free layer 13. When the magnetic order of the free layer 13 is parallel to the magnetic order of the pinned layer 92, the magnetoresistance element 91 exhibits a low electrical resistance. When the magnetic order of the free layer 13 is antiparallel to the magnetic order of the pinned layer 92, the magnetoresistance element 91 exhibits a high electrical resistance. The magnetic orders of the free layer 13, the pinned layer 92, and the pinning layer 93 are aligned in an in-plane direction with respect to the interface between the layers. The hollow arrows in FIG. 27 indicate the directions of the magnetic orders. An upper electrode layer 17 is stacked on the pinning layer 93. The upper electrode layer 17 is configured in the same manner as described above.

The pinning layer 93 is made of the same antiferromagnet as that of the free layer 13. The antiferromagnet of the pinning layer 93 has a magnetic structure with macroscopically broken time-reversal symmetry. Such an antiferromagnet includes non-collinear antiferromagnets. The antiferromagnet can exhibit the anomalous Hall effect due to the symmetry breaking. Other examples of the antiferromagnet include antiferromagnetic metals containing manganese (Mn), and collinear antiferromagnets having a rutile crystal structure. Examples of the antiferromagnetic metals include Mn₃X (X is one or more selected from the group consisting of Sn, Ge, Ga, Rh, Pt, and Ir), Mn₃XN (X is one or more selected from the group consisting of Ga, Sn, and Ni), and gamma-type Mn alloys having a face-centered cubic (fcc) structure. As long as the magnetic structure with macroscopically broken time-reversal symmetry is maintained, deviations in the composition ratio and the presence of contamination can be tolerated. Examples of the gamma-type Mn alloys include Mn₁₋ₓFex, Mn₁₋ₓRhx, and Mn₁₋ₓPdx. Examples of the collinear antiferromagnets include RuO₂ and MnsSi₃. The coercivity of the pinned layer 92 is designed to be greater than that of the free layer 13 due to the effect of the pinning layer 93.

The free layer 13 and the pinning layer 93 can be deposited separately by DC sputtering. In a chamber, the pressure is maintained at, for example, 0.5 [Pa] under an argon (Ar) atmosphere at room temperature. The power is set to 60 [W], for example. After the deposition, the free layer 13 and the pinning layer 93 are individually annealed at 500° C. for 30 minutes, for example. The annealing causes crystallization in the free layer 13 and the pinning layer 93. After the annealing, the free layer 13 and the pinning layer 93 are naturally cooled to room temperature.

In the magnetoresistance element 91 according to the present embodiment, since the free layer 13 is made of an antiferromagnet, the reversal speed of the magnetic order is higher than that of a free layer made of a ferromagnet. Therefore, in the free layer 13, the power consumption associated with the magnetic order reversal can be reduced. In addition, since a hard magnetic order is established in the pinned layer 92 through the interlayer exchange coupling, it is possible to favorably maintain a change in the electrical resistance.

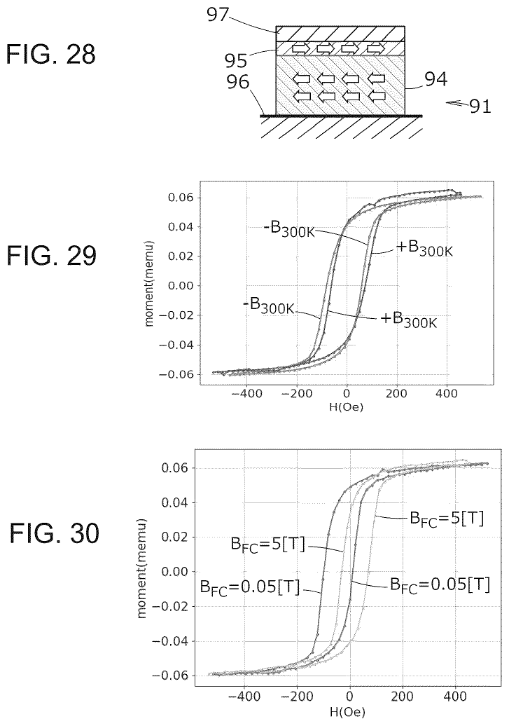

The inventors conducted experiments to investigate the interlayer exchange coupling between the pinned layer 92 and the pinning layer 93. As shown in FIG. 28, in the experiments, the inventors prepared a coupling film including a Mn₃Sn layer 94 [thickness: 30 nm] and a permalloy layer 95 (Ni_{0.8}Fe_{0.2}) [thickness: 5 nm]. The Mn₃Sn layer 94 was formed to have a thickness of 35 [nm]. The permalloy layer 95 was formed to have a thickness of 5 [mm]. The Mn₃Sn layer 94 was deposited at room temperature on a SiO₂/Si substrate 96 using DC sputtering. The pressure inside a chamber was maintained at 1.2 [Pa] under an argon (Ar) atmosphere. The power was set to 60 [W].

After the deposition, the Mn₃Sn layer 94 was annealed at 500° C. for 30 minutes in vacuum. The Mn₃Sn layer 94 was crystallized by annealing. After natural cooling to room temperature, the permalloy layer 95 [thickness: 5 nm] was deposited on the Mn₃Sn layer 84 using electron beam evaporation. The evaporation rate of permalloy was set to 0.3 [angstroms/s].

Thereafter, an AlOₓ layer 97 as a capping layer with a thickness of 5 [nm] was deposited on the permalloy layer 95 using RF sputtering. The pressure inside a chamber was maintained at 0.2 [Pa] under an argon (Ar) atmosphere. The RF power was set to 100 [W]. The deposition rate was set to 1.6 [nm/min].

The inventors evaluated the magnetic coupling of the permalloy/Mn₃Sn coupling film by measuring in-plane magnetization of the permalloy. As shown in FIG. 29, when a magnetic field of +5 [T] was applied in an in-plane direction at a temperature of 300 [K], the magnetic coupling between the Mn₃Sn layer 94 and the permalloy layer 95 was observed at room temperature. The magnetization of the permalloy is shifted in a positive direction under the in-plane magnetic field of B=+5 [T]. The magnetization of the permalloy is shifted in a negative direction by approximately the same amount as in the positive direction under the in-plane magnetic field of B=−5 [T].

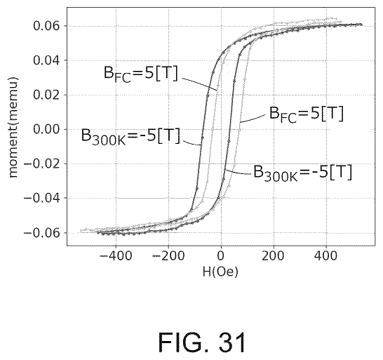

Next, after heating to 450 [K], which is sufficiently higher than the Neel temperature of Mn₃Sn, an in-plane magnetization of +5 [T] was applied, followed by cooling to 300 [K]. As shown in FIG. 30, the magnetization of the permalloy was observed to be shifted in the positive direction, with a shift amount greater than that in the aforementioned isothermal process. Subsequently, an in-plane magnetic field of B=−5 [T] was applied to the coupling film, and the magnetization of the permalloy was measured. As shown in FIG. 31, a shift in the negative direction was observed.

### REFERENCE SIGNS LIST

11: magnetoresistance element
12: electrode (lower electrode layer)
13: free layer
14: non-magnetic layer
15: pinned layer
16: pinning layer
17: electrode (upper electrode layer)
41: magnetic memory device
42: magnetoresistance element
43: spin Hall layer
51: magnetic memory device
52: magnetoresistance element

1. A magnetoresistance element, comprising:
a free layer made of an antiferromagnet;
a non-magnetic layer stacked on the free layer;
a pinned layer stacked on the non-magnetic layer and made of an antiferromagnet; and
a pinning layer stacked on the pinned layer and made of a magnetic material that is magnetically harder than the pinned layer.

2. The magnetoresistance element according to claim 1, wherein
the pinning layer is made of an antiferromagnet or a synthetic antiferromagnet.

3. The magnetoresistance element according to claim 2, wherein
the antiferromagnet of the free layer has a magnetic structure that exhibits an anomalous Hall effect.

4. The magnetoresistance element according to claim 3, wherein
the antiferromagnet of the pinned layer has a magnetic structure that exhibits an anomalous Hall effect.

5. The magnetoresistance element according to claim 4, wherein
the non-magnetic layer is made of an insulator.

6. The magnetoresistance element according to claim 4, wherein
the non-magnetic layer is made of a metal.

7. A magnetic memory device, comprising:
a free layer made of an antiferromagnet;
a non-magnetic layer stacked on the free layer;
a pinned layer stacked on the non-magnetic layer and made of an antiferromagnet;
a pinning layer stacked on the pinned layer and made of a magnetic material that is magnetically harder than the pinned layer; and
a spin Hall layer that is in contact with the free layer and configured to exhibit a spin Hall effect when an electric current flows through the spin Hall layer parallel to an interface with the free layer.

8. A magnetic memory device, comprising:
a free layer made of an antiferromagnet;
a non-magnetic layer stacked on the free layer;
a pinned layer stacked on the non-magnetic layer and made of an antiferromagnet;
a pinning layer stacked on the pinned layer and made of a magnetic material that is magnetically harder than the pinned layer; and
a pair of electrode terminals configured to introduce an electric current into the free layer in an out-of-plane direction.

9. A magnetoresistance element, comprising:
a pinned layer made of an antiferromagnet; and
a pinning layer that is magnetically harder than the pinned layer.

10. A magnetoresistance element, comprising:
a free layer made of an antiferromagnet;
a non-magnetic layer stacked on the free layer;
a pinned layer stacked on the non-magnetic layer and made of a ferromagnet; and
a pinning layer stacked on the pinned layer and made of a magnetic material that is magnetically harder than the ferromagnet of the pinned layer.

11. An information processing system comprising the magnetoresistance element according to claim 1.

12. An information processing system comprising the magnetic memory device according to claim 7.

13. A method of controlling a magnetic memory device, the magnetic memory device comprising: a free layer made of an antiferromagnet; a non-magnetic layer stacked on the free layer; a pinned layer stacked on the non-magnetic layer and made of an antiferromagnet; and a pinning layer stacked on the pinned layer and made of a magnetic material that is magnetically harder than the pinned layer, the method comprising:
manipulating a magnetic order in the free layer due to spin torque.

14. A method of controlling a magnetic memory device, the magnetic memory device comprising: a free layer made of an antiferromagnet; a non-magnetic layer stacked on the free layer; a pinned layer stacked on the non-magnetic layer and made of an antiferromagnet; a pinning layer stacked on the pinned layer and made of a magnetic material that is magnetically harder than the pinned layer; and a spin Hall layer that is in contact with the free layer and configured to exhibit a spin Hall effect when an electric current flows through the spin Hall layer parallel to an interface with the free layer, the method comprising:
reversing a magnetic order in the free layer due to spin-orbit torque induced by the spin Hall effect.

15. A method of controlling a magnetic memory device, the magnetic memory device comprising: a free layer made of an antiferromagnet; a non-magnetic layer stacked on the free layer; a pinned layer stacked on the non-magnetic layer and made of an antiferromagnet; and a pinning layer stacked on the pinned layer and made of a magnetic material that is magnetically harder than the pinned layer, the method comprising:
causing a write current to flow through the free layer in an out-of-plane direction, thereby reversing a magnetic order in the free layer due to spin-transfer torque.
